(19) United States
(12) Patent Application Publication
(10) Pub. No.: US 2020/0303646 A1
(43) Pub. Date: Sep. 24, 2020

(54) METHOD FOR FORMING LIGHT-EMITTING LAYER AND METHOD FOR PRODUCING LIGHT-EMITTING ELEMENT

(71) Applicant: DIC Corporation, Tokyo (JP)

(72) Inventors: Toru Tsuruta, Sakura-shi (JP); Hidenari Akiyama, Sakura-shi (JP)

(73) Assignee: DIC Corporation, Tokyo (JP)

(21) Appl. No.: 16/651,615

(22) PCT Filed: Sep. 25, 2018
(86) PCT No.: PCT/JP2018/035306

§ 371 Date: May 21, 2020

(30) Foreign Application Priority Data
Oct. 4, 2017 (JP) 2017-194106

(51) Int. Cl. H01L 51/00; H01L 51/56

(52) U.S. Cl. CPC H01L 51/0005; H01L 51/502; H01L 2251/556; H01L 51/56

(57) ABSTRACT

The method for forming a light-emitting layer includes the steps of: preparing an ink containing particles and a dispersion medium with a boiling point of 200° C. or more at atmospheric pressure, the particles containing light-emitting semiconductor nanocrystals and a dispersant supported on the semiconductor nanocrystals; supplying the ink to a substrate to form a coating film on the substrate; placing the substrate, on which the coating film is formed, in a chamber, and reducing the internal pressure of the chamber to a first pressure in the range of 1 to 500 Pa and holding the first pressure for 2 minutes or more to remove the dispersion medium from the coating film; and reducing the internal pressure of the chamber to a second pressure that is lower than the first pressure and holding the second pressure for a predetermined time to further remove the dispersion medium from the coating film.

### TECHNICAL FIELD

The present invention relates to a method for forming a light-emitting layer and a method for producing a light-emitting device.

### BACKGROUND ART

Devices that utilize electroluminescence, such as LEDs and organic EL devices, are widely used as light sources for various display apparatuses. In recent years, light-emitting devices that include light-emitting semiconductor nanocrystals, such as quantum dots and quantum rods, as light-emitting materials have attracted attention. Light emitted from semiconductor nanocrystals has good color reproducibility due to its narrower spectral width and wider color gamut than organic EL devices. A light-emitting layer of such a light-emitting device is formed by applying an ink containing semiconductor nanocrystals dispersed in a dispersion medium to form a coating film and drying the coating film.

Uniform and dense existence of semiconductor nanocrystals in a light-emitting layer is important for the light-emitting layer (light-emitting device) to have good light-emitting properties. For example, in Patent Literature 1, a coating film is dried under reduced pressure in two steps using a dry pump and a turbo-molecular pump. In the drying method described in Patent Literature 1, however, the drying time of a coating film with the dry pump at a relatively low degree of vacuum is too short.

Thus, a high degree of vacuum with the turbo-molecular pump causes a dispersion medium to be rapidly removed from the coating film, thus decreasing the smoothness of the coating film. Thus, semiconductor nanocrystals agglomerate in the coating film, and a light-emitting layer (light-emitting device) with sufficient light-emitting properties cannot be produced.

### CITATION LIST

### Patent Literature

PTL 1: Japanese Unexamined Patent Application Publication No. 2010-80167

### SUMMARY OF INVENTION

### Technical Problem

It is an object of the present invention to provide a method for producing a light-emitting layer with good light-emitting properties and a method for producing a light-emitting device with good light emitting properties.

### Solution to Problem

Such objects of the present invention can be achieved by the following (1) to (6).

(1) A method for forming a light-emitting layer, including the steps of:

preparing an ink containing particles and a dispersion medium with a boiling point of 200° C. or more at atmospheric pressure, the particles containing light-emitting semiconductor nanocrystals and a dispersant supported on the semiconductor nanocrystals;

supplying the ink to a substrate to form a coating film on the substrate;

placing the substrate, on which the coating film is formed, in a chamber, and reducing the internal pressure of the chamber to a first pressure in the range of 1 to 500 Pa and holding the first pressure for 2 minutes or more to remove the dispersion medium from the coating film; and

reducing the internal pressure of the chamber to a second pressure that is lower than the first pressure and holding the second pressure for a predetermined time to further remove the dispersion medium from the coating film.

(2) The method for forming a light-emitting layer according to (1), wherein the temperature at which the first pressure is held ranges from room temperature to 60° C.

(3) The method for forming a light-emitting layer according to (1) or (2), wherein the second pressure is 5×10⁻² Pa or less.

(4) The method for forming a light-emitting layer according to any one of (1) to (3), wherein the temperature at which the second pressure is held ranges from room temperature to 150° C.

(5) The method for forming a light-emitting layer according to any one of (1) to (4), wherein the predetermined time ranges from 2 to 30 minutes.

(6) A method for producing a light-emitting device, including the steps of:

forming a light-emitting layer by the method for forming a light-emitting layer according to any one of (1) to (5); and

forming an anode or cathode before or after the step of forming a light-emitting layer.

### ADVANTAGEOUS EFFECTS OF INVENTION

The present invention can provide a light-emitting layer with good light-emitting properties and a light-emitting device with good light-emitting properties.

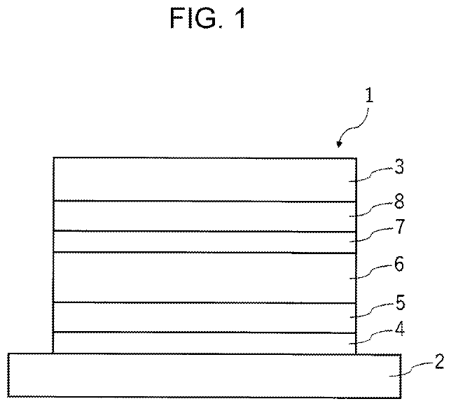

FIG. 1 is a cross-sectional view of an embodiment of a light-emitting device produced by a method for producing a light-emitting device according to the present invention.

### DESCRIPTION OF EMBODIMENTS

A method for producing a light-emitting layer and a method for producing a light-emitting device according to the present invention are described in detail below with preferred embodiments with reference to accompanying drawings.

### Ink

An ink for use in the present invention contains particles, which contain light-emitting semiconductor nanocrystals and a dispersant supported on the semiconductor nanocrystals, and a dispersion medium for dispersing the particles.

If necessary, the ink may contain a charge-transport material and a surfactant,, for example.

### Particles

The particles contain semiconductor nanocrystals and a dispersant supported on the semiconductor nanocrystals. Semiconductor nanocrystals (hereinafter also referred to simply as “nanocrystals”) are nanoscale crystals (nanocrystal particles) that absorb excitation light and emit fluorescence or phosphorescence, for example, crystals with a maximum particle size of 100 nm or less as measured with a transmission electron microscope or a scanning electron microscope.

For example, nanocrystals can be excited by light energy or electrical energy at a specified wavelength and emit fluorescence or phosphorescence.

The nanocrystals may be red-light-emitting crystals that emit light with an emission peak in the wavelength range of 605 to 665 nm (red light), green-light-emitting crystals that emit light with an emission peak in the wavelength range of 500 to 560 nm (green light), or blue-light-emitting crystals that emit light with an emission peak in the wavelength range of 420 to 480 nm (blue light). In one embodiment, an ink preferably contains at least one type of nanocrystals among these types of nanocrystals.

The emission peak wavelength of the nanocrystals can be determined in a fluorescence spectrum or a phosphorescence spectrum measured with as ultraviolet-visible spectrophotometer, for example.

The red-light-emitting nanocrystals preferably have an emission peak wavelength of 665 nm or less, 663 nm or less, 660 nm or less, 658 nm or less, 655 nm or less, 653 nm or less, 651 nm or less, 650 nm or less, 647 nm or less, 645 nm or less, 643 nm or less, 640 nm or less, 637 nm or less, 635 nm or less, 632 nm or less, or 630 nm or less, and preferably have an emission peak wavelength of 628 nm or more, 625 nm or more, 623 nm or more, 620 nm or more, 615 nm or more, 610 nm or more, 607 nm or more, or 605 nm or more.

Any of these upper limits and lower limits may be combined. Also in the following similar description, any of each upper limit and each lower limit may be combined.

The green-light-emitting nanocrystals preferably have an emission peak wavelength of 560 nm or less, 557 nm or less, 555 nm or less, 550 nm or less, 547 nm or less, 545 nm or less, 543 nm or less, 540 nm or less, 537 nm or less, 535 nm or less, 532 nm or less, or 530 nm or less, and preferably have an emission peak wavelength of 528 nm or more, 525 nm or more, 523 nm or more, 520 nm or more, 515 nm or more, 510 nm or more, 507 nm or more, 505 nm or more, 503 nm or more, or 500 nm or more.

The blue-light-emitting nanocrystals preferably have an emission peak wavelength of 480 nm or less, 477 nm or less, 475 nm or less, 470 nm or less, 467 nm or less, 465 nm or less, 463 nm or less, 460 rim or less, 457 nm or less, 455 nm or less, 452 nm or less, or 450 nm or less, and preferably have an emission peak wavelength of 450 nm or more, 445 nm or more, 440 nm or more, 435 nm or more, 430 nm or more, 428 nm or more, 425 nm or more, 422 nm or more, or 420 nm or more.

The wavelength (emission color) of light emitted by nanocrystals depends on the size (for example, particle size) of the nanocrystals according to the solution of the Schrodinger wave equation of a potential well model and also depends on the energy cap of the nanocrystals. Thus, the constituent material and size of nanocrystals can be changed to select (adjust) the emission color.

The nanocrystals may be formed of a semiconductor material and have various structures. For example, the nanocrystals may be composed entirely of a core formed of a first semiconductor material or may be composed of a core formed of the first semiconductor material and a shell covering at least part of the core and formed of a second semiconductor material different from the first semiconductor material. In other words, the nanocrystals may have a structure composed entirely of a core (core structure) or composed of a core and a shell (core/shell structure).

In addition to the shell (first shell) formed of the second semiconductor material, the nanocrystals may further have a shell (second shell) covering at least part of the shell and formed of a third semiconductor material different from the first and second semiconductor materials. In other words, the nanocrystals may have a structure composed of the core, the first shell, and the second shell (core/shell/shell structure).

Each of the core and the shells may be formed of mixed crystals containing two or more semiconductor materials (for example, CdSe+CdS, CIS+ZnS, etc.).

The nanocrystals are preferably formed of at least one semiconductor material selected from the group consisting of group II-VI semiconductors, group III-V semiconductors, group I-III-VI semiconductors, group IV semiconductors, and group I-II-IV-VI semiconductors.

Specific examples of the semiconductor materials include CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, SiGe, AgInSe₂, CuGaSe₂, CuInS₂, CuGaS₂, CuInSe₂, AgInS₂, AgGaSe₂, AgGaS₂, and C.

The semiconductor materials preferably contain at least one selected from the group consisting of CdS, CdSe, CdTe, ZnS, ZnSe, ZnTe, ZnO, HgS, HgSe, HgTe, InP, InAs, InSb, GaP, GaAs, GaSb, AgInS₂, AgInSe₂, AgInTe₂, AgGaS₂, AgGaSe₂, AgGaTe₂, CuInS₂, CuInSe₂, CuInTe₂, CuGaS₂, CuGaSe₂, CuGaTe₂, Si, C, Ge, and Cu₂ZnSnS₄.

The nanocrystals formed of these semiconductor materials can have an easily-controlled emission spectrum, high reliability, low production costs, and improved mass productivity.

Examples of the red-light-emitting nanocrystals include CdSe nanocrystals; rod-like CdSe nanocrystals; rod-like nanocrystals with a CdS shell and a CdSe core; rod-like nanocrystals with a CdS shell and a ZnSe core; nanocrystals with a CdS shell and a CdSe core; nanocrystals with a CdS she and a ZnSe core; nanocrystals with a ZnS shell and an InP core; nanocrystals with a ZnS shell and a CdSe core; CdSe and ZnS mixed nanocrystals; rod-like CdSe and ZnS mixed nanocrystals; InP nanocrystals; rod-like InP nanocrystals; CdSe and CdS mixed nanocrystals; rod-like CdSe and CdS mixed nanocrystals; ZnSe and CdS mixed nanocrystals; and rod-like ZnSe and CdS mixed nanocrystals.

Examples of the green-light-emitting nanocrystals include CdSe nanocrystals; rod-like CdSe nanocrystals; nanocrystals with a ZnS shell and an InP core; nanocrystals with a ZnS shell and a CdSe core; CdSe and ZnS mixed nanocrystals; and rod-like CdSe and ZnS mixed nanocrystals.

Examples of the blue-light-emitting nanocrystals include ZnSe nanocrystals; rod-like ZnSe nanocrystals; ZnS nanocrystals; rod-like ZnS nanocrystals; nanocrystals with a ZnSe shell and a ZnS core; rod-like nanocrystals with a ZnSe shell and a ZnS core; CdS nanocrystals; and rod-like Cds nanocrystals.

The color of light emitted by nanocrystals with a fixed chemical composition can be altered to red or green by adjusting the average particle size of the nanocrystals.

Nanocrystals by themselves preferably have minimal adverse effects on human bodies. Thus, nanocrystals containing minimal amounts of cadmium, selenium, or the like are preferably used alone. When nanocrystals containing these elements (cadmium, selenium, etc.) are used, the nanocrystals are preferably used in combination with other nanocrystals to minimize the amounts of these elements.

The nanocrystals may have any shape, may have any geometrical shape, and may have any irregular shape. For example, the nanocrystals may be spherical, regular tetrahedral, ellipsoidal, pyramid-like, discoid, branched, netlike, or rod-like. The nanocrystals preferably have a less directional shape (for example, spherical, regular tetrahedral, etc.) The use of nanocrystals with such a shape can improve the uniformity and fluidity of the ink.

The nanocrystals preferably have an average particle size (volume-average size) of 40 nm or less, more preferably 30 nm or less, still more preferably 20 nm or less. Nanocrystals with such an average particle size are preferred because such nanocrystals can easily emit light with a desired wavelength.

The nanocrystals preferably have an average particle size (volume-average size) of 1 nm or more, more preferably 1.5 nm or more, still more preferably 2 nm or more. Nanocrystals with such an average particle size are also preferred, because such nanocrystals can easily emit light with a desired wavelength and also have improved dispersibility in the ink and improved storage stability.

The average particle size (volume-average size) of the nanocrystals can be measured with a transmission electron microscope or a scanning electron microscope and can be calculated as a volume-average size.

The nanocrystals have surface atoms that can function as coordination sites and therefore have high reactivity. Due to their high reactivity and higher surface area than common pigments, the nanocrystals are more likely to agglomerate.

The nanocrystals emit light due to the quantum size effect. Thus, agglomeration of the nanocrystals causes a quenching phenomenon, decreases the fluorescence quantum yield, and decreases luminance and color reproducibility. Thus, inks in which nanocrystals are dispersed in a dispersion medium as in the present invention tend to cause a degradation in light-emitting properties due to agglomeration, unlike inks in which an organic light-emitting material is dissolved in a solvent. Thus, it is important for an ink according to the present invention to be prepared such that nanocrystals have high dispersion stability.

### Dispersant

Accordingly, in the present invention, a dispersant (organic ligand) miscible with a dispersion medium is supported (held) on the surface of nanocrystals, or in other words the surface of nanocrystals is inactivated by the dispersant. The dispersant can improve the dispersion stability of the nanocrystals in the ink.

The dispersant is supported on the surface of the nanocrystals, for example, by a covalent bond, a coordinate bond, an ionic bond, a hydrogen bond, or a van der Waals bond. The term “support”, as used herein, collectively refers to the state in which a dispersant is adsorbed on, adheres to, or is bonded to the surface of nanocrystals. The dispersant can be detached from the surface of the nanocrystals, keep an equilibrium between the support by the nanocrystals and the detachment from the nanocrystal , and repeat these.

The dispersant may be any compound that can improve the dispersion stability of nanocrystals in the ink. The dispersant may be a low-molecular-weight dispersant or a high-molecular-weight dispersant. The term “low-molecular-weight”, as used herein, refers to a molecule with a weight-average molecular weight (Mw) of 5,000 or less. The term “high-molecular-weight”, as used herein, refers to a molecule with a weight-average molecular weight (Mw) of more than 5,000.

The term “weight-average molecular weight (Mw)”, as used herein, refers to a molecular weight measured by gel permeation chromatography (GPC) based on polystyrene standards.

Examples of the low-molecular-weight dispersant include oleic acid; compounds containing a phosphorus atom, such as triethyl phosphate, trioctylphosphine (TOP), trioctylphosphine oxide (TOPO), hexylphosphonic acid (HPA), tetradecylphosphonic acid (TDPA), and octylphosphinic acid (OPA); compounds containing a nitrogen atom, such as oleylamine, octylamine, trioctylamine, and hexadecylamine; and compounds containing a sulfur atom, such as 1-decanethiol, octanethiol, dodecanethiol, and amyl sulfide.

Examples of the high-molecular-weight dispersant include high-molecular-weight compounds with a functional group that can be supported on the surface of the nanocrystals.

Examples of such a functional group include a primary amino group, a secondary amino group, a tertiary amino group, a phosphoric acid group, a phosphoric acid ester group, a phosphonic acid group, a phosphonic acid ester group, a phosphinic acid group, a phosphinic acid ester group, a thiol group, a thioether group, a sulfonic acid group, a sulfonic acid ester group, a carboxylic acid group, a carboxylic acid ester group, a hydroxy group, a ether group, an imidazolyl group, a triazinyl group, a pyrrolidonyl group, an isocyanuric acid group, a boric acid ester group, and a boronic acid group.

Among these, a plurality of functional groups are preferably combined; a primary amino group, a secondary amino group, a tertiary amino group, a carboxylic acid ester group, a hydroxy group, and an ether group are preferred in terms of the ease of synthesis of a high-molecular-weight compound with increased ability to be supported on nanocrystals, and a phosphoric acid group, a phosphoric acid ester group, a phosphonic acid group, a phosphonic acid ester group, and a carboxylic acid group are preferred in terms of sufficient ability to be supported on nanocrystals even by itself.

Furthermore, a primary amino group, a secondary amino group, a tertiary amino group, a phosphoric acid group, a phosphonic acid group, and a carboxylic acid group are more preferred in terms of high ability to be supported on nanocrystals in the ink.

Examples of a high-molecular-weight dispersant with a primary amino group include linear amines, such as poly(alkylene glycol) amines, polyester amines, urethane-modified polyester amines, poly(alkylene glycol) diamines, polyester diamines, and urethane-modified polyester diamines, and (meth)acrylic polymers with an amino group on a side chain, that is, comb-like polyamines.

Examples of a high-molecular-weight dispersant with a secondary amino group include comb block copolymers that have a main chain including a linear polyethyleneimine backbone with many secondary amino groups and a side chain, such as a polyester, acrylic resin, or polyurethane.

Examples of a high-molecular-weight dispersant with a tertiary amino group include star-shaped amines, such as tri(poly(alkylene glycol)) amines.

Examples of high-molecular-weight dispersants with a primary amino group, a secondary amino group, and a tertiary amino group include high-molecular-weight compounds with a linear or multi-branched polyethyleneimine block a ad a polyethylene glycol) block described in Japanese Unexamined Patent Application Publication Nos. 2008-037884, 2008-037949, 2008-03818, and 2010-007124.

Examples of a high-molecular-weight dispersant with a phosphoric acid group include poly(alkylene glycol) monophosphates, poly(alkylene glycol) monoalkyl ether monophosphates, perfluoroalkyl polyoxyalkylene phosphates, perfluoroalkyl sulfonamide polyoxyalkylene phosphates, homopolymers of monomers, such as acid phosphoxyethyl mono(meth)acrylate, acid phosphoxypropyl mono (meth) acrylate, and acid phosphoxy polyoxyalkylene glycol mono(meth)acrylates, copolymers of these monomers and other comonomers; and (meth)acrylic polymers with a phosphoric acid group produced by a method described in Japanese Patent No. 4697355.

For a high-molecular-weight dispersant with a phosphoric acid group, an alkali metal hydroxide or an alkaline-earth metal hydroxide may be allowed to react to form a salt and adjust the pH.

Examples of a high-molecular-weight dispersant with a phosphonic acid group include poly(alkylene glycol) monoalkyl phosphonates, poly(alkylene glycol) monoalkyl ether monoalkyl phosphonates, perfluoroalkyl polyoxyalkylene alkyl phosphonates, perfluoroalkyl sulfonamide polyoxyalkylene alkyl phosphonates, polyethylene phosphonic acid; homopolymers of monomers, such as vinylphosphonic acid, (meth) acryloyloxyethylphosphonic acid, (meth)acryloyloxypropylphosphonic acid, and (meth)acryloyloxypolyoxyalkylene glycol phosphonic acid, and copolymers of these monomers and other comonomers.

For a high-molecular-weight dispersant with a phosphonic acid group, an alkali metal hydroxide or an alkaline-earth metal hydroxide may be allowed to react to form a salt and adjust the pH.

Examples of a high-molecular-weight dispersant with a phosphinic acid group include poly(alkylene glycol) dialkyl phosphinates, perfluoroalkyl polyoxyalkylene dialkyl phosphinates, perfluoroalkyl sulfonamide polyoxyalkylene dialkyl phosphinates, polyethylenephosphinic acid; homopolymers of monomers, such as vinylphosphinic acid, (meth)acryloyloxydialkylphosphinic acids, and (meth)acryloyloxypolyoxyalkylene glycol dialkylphosphinic acids, and copolymers of these monomers and other comonomers. For a high-molecular-weight dispersant with a phosphinic acid group, an alkali metal hydroxide or an alkaline-earth metal hydroxide may be allowed to react to form a salt and adjust the pH.

Examples of a high-molecular-weight dispersant with a thiol group include polyvinylthiol and poly(alkylene glycol) ethylenethiols.

Examples of a high-molecular-weight dispersant with a thioether group include poly(alkylene glycol) thioethers produced by a reaction between mercaptopropionic acid and a glycidyl-modified poly(alkylene glycol) described in Japanese Unexamined Patent Application Publication No. 2013-60637.

Examples of a high-molecular-weight dispersant with a sulfonic acid group include poly(alkylene glycol) monoalkyl sulfonates, poly(alkylene glycol) monoalkyl ether monoalkyl sulfonates, perfluoroalkyl polyoxyalkylene alkyl sulfonates, perfluoroalkyl sulfonamide polyoxyalkylene alkyl sulfonates, polyethylenesulfonic acid; homopolymers of monomers, such as vinylsulfonic acid, (meth)acryloyloxyalkylsulfonic acids, (meth)acryloyloxypolyoxyalkylene glycol sulfonic acids, and polystyrene sulfonate), and copolymers of these monomers and other comonomers.

For a high-molecular-weight dispersant with a sulfonic acid group, an alkali metal hydroxide or an alkaline-earth metal hydroxide may be allowed to react to form a salt and adjust the pH.

Examples of a high-molecular-weight dispersant with a carboxylic acid group include poly alkylene glycol) carboxylic acids, perfluoroalkyl polyoxyalkylene carboxylic acids, polyethylene carboxylic acid, polyester monocarboxylic acids, polyester dicarboxylic acids, urethane-modified polyester monocarboxylic acids, urethane-modified polyester dicarboxylic acids; homopolymers of monomers, such as vinylcarboxylic acid, (meth)acryloyloxyalkyl carboxylic acids, and (meth)acryloyloxypolyoxyalkylene glycol carboxylic acids, and copolymers of these monomers and other comonomers.

For a high-molecular-weight dispersant with a carboxylic acid group, an alkali metal hydroxide or an alkaline-earth metal hydroxide may be allowed to react to form a salt and adjust the pH.

A high-molecular-weight dispersant with an ester group can be produced by dehydration condensation between the high-molecular-weight dispersant with a carboxylic acid group and, for example, a monoalkyl alcohol.

Examples of a high-molecular-weight dispersant with a pyrrolidonyl group include polyvinylpyrrolidone.

A high-molecular-weight dispersant with a particular functional group may be a synthetic product or a commercial product.

Examples of the commercial product include DISPERBYK series manufactured by BYK-Chemie, such as DISPERBYK-102, DISPERBYK-103, DISFERBYK-108, DISPERBYK-109, DISPERBYK-110, DISPERBYK-111, DISFERBYK-118, DISPERBYK-140, DISPERBYK-145, DISPERBYK-161, DISPERBYK-164, DISPERBYK-168, DISPERBYK-180, DISPERBYK-182, DISPERBYK-184, DISPERBYK-185, DISPERBYK-190, DISPERBYK-191, DISPERBYK-2000, DISPERBYK-2001, DISPERBYK-2008, DISPERBYK-2009, DISPERBYK-2010, DISPERBYK-2012, DISPERBYK-2013, DISFERBYK-2022, DISPERBYK-2025, DISPERBYK-2050, DISPERBYK-2060, DISPERBYK-9070, and DISPERBYK-9077; TEGO Dispers series manufactured by Evonik Industries AG., such as TEGO Dispers 610, TEGO Dispers 630, TEGO Dispers 650, TEGO Dispers 651, TEGO Dispers 652, TEGO Dispers 655, TEGO Dispers 6600, TEGO Dispers 662C, TEGO Dispers 670, TEGO Dispers 685, TEGO Dispers 700, TEGO Dispers 710, TEGO Dispers 715W, TEGO Dispers 740W, TEGO Dispers 750W, TEGO Dispers 752W, TEGO Dispers 755W, and TEGO Dispers 760W; EFKA series manufactured by BASF, such as. EFKA-44, EFKA-46, EFKA-47, EFKA-48, EFKA-4010, EFKA-4050, EFKA-4055, EFKA-4020, EFKA-4015, EF A-4060, EFKA-4300, EFS-4330, EFKA-4400, EFKA-4406, EFKA-4510, and EFKA-4800; SOLSPERSE series manufactured by Lubrizol Japan Limited, such as SOLSPERS-3000, SOLSPERS-9000, SOLSPERS-16000, SOLSPERS-17000, 3OLSPERS-18000, SOLSPERS-13940, SOLSPERS-20000, SOLSPERS-24000, SOLSPERS-32550, and SOLSPERS-71000; Ajisper series manufactured by Ajinomoto Fine-Techno Co., Inc., such Ajisper (AJISPER) PB-821, Ajisper PB-822, and Ajisper PB-893; DISPARLON series manufactured by Kusumoto Chemicals, Ltd., such as DISPARLON DA325, DISPARLON DA375, DISPARLON DA1800, and DISPARLON DA7301; and Flowlen series manufactured by Kyoeisha Chemical Co., Ltd., such as Flowlen (FLOWLENE) DOPA-17HF, Flowlen DOPA-15BHF, Flowlen DOPA-33, and Flowlen DOPA-44.

These high-molecular-weight dispersants may be used alone or in combination.

The molecules of such a dispersant may be almost entirely or partly supported in contact with the nanocrystals. In both states, the dispersant appropriately performs a dispersive function of stably dispersing the nanocrystals in the dispersion medium.

From this point of view, the dispersant preferably has a weight-average molecular weight (Mw) of 50,000 or less, more preferably approximately 100 to 50,000. Among the low-molecular-weight dispersants, compounds that are not polymers have a mass expressed by “molecular weight” rather than the “weight-average molecular weight”.

A dispersant with a weight-average molecular weight equal to or higher than the lower limit has high ability to be supported on nanocrystals and can ensure sufficient dispersion stability of the nanocrystals in the ink. On the other hand, a dispersant with a weight-average molecular weight equal to or lower than the upper limit has a sufficient number of functional groups per unit weight, does not have excessively high crystallinity, and can improve the dispersion stability of nanocrystals in the ink. Such a dispersant does not have an excessively high weight-average molecular weight and can also prevent or reduce the inhibition of charge transfer in the light-emitting layer.

The amount of dispersant in particular, high-molecular-weight dispersant) is preferably 50% or less by mass of the amount of nanocrystals. This reduces the amount of unnecessary organic materials left or deposited on the surface of nanocrystals when the nanocrystals support the dispersant. Thus, the dispersant layer is less likely to become an insulating layer to inhibit charge transfer and can prevent degradation in light-emitting properties.

The amount of dispersant is preferably 1% or more by mass, more preferably 3% or more by mass, still more preferably 5% or more by mass, of the amount of nanocrystals. This can ensure sufficient dispersion stability of the nanocrystals in the ink.

### Charge-Transport Material

Charge-transport materials typically have the function of transporting positive holes and electrons injected into a light-emitting layer.

Any charge-transport materials that have the function of transporting positive holes and electrons may be used. Charge-transport materials are classified into high-molecular-weight charge-transport materials and low-molecular-weight charge-transport materials.

Examples of the high-molecular-weight charge-transport materials include, but are not limited to, vinyl polymers, such as poly(9-vinylcarbazole) (PVK); conjugated compound polymers, such as poly[N,N′-bis(4-butylphenyl)-N,N′-bis(phenyl)-benzidine] (poly-TPA), polyfluorene (PF), poly[N,N′-bis(4-butylphenyl)-N,N′-bis(phenyl)-benzidine (Poly-TPD), poly[(9,9-dioctylfluorenyl-2,7-diyl)-co-(4,4′-(N-(4-sec-butylphenyl)diphenylamine)] (TFB), and poly(phenylene vinylene) (PPV), and copolymers containing these monomer units.

Examples of the low-molecular-weight charge transport materials include, but are not limited to, carbazole derivatives, such as 4,4′-bis(9H-carbazol-9-yl)biphenyl (CBP), 9,9′-(p-tert-butylphenyl)-3,3-biscarbazole, 1,3-dicarbazolylbenzene (mCP), 4,4′-bis(9-carbazolyl)-2,2′-dimethylbiphenyl (CDBP), N,N′-dicarbazolyl-1,4-dimethylbenzene (DCB), and 5,11-diphenyl-5,11-dihydroindolo[3,2-b]carbazole; aluminum complexes, such as bis(2-methyl-8-quinolinolate)-4-(phenylphenolate) aluminum (BAlq), phosphine oxide derivatives, such as 2,7-bis(diphenylphosphine oxide)-9,9-dimethylfluorene (P06); silane derivatives, such as 3,5-bis(9-carbazolyl)tetraphenyisilane (SimCP) and 1,3-bis triphenylsilyl)benzene (UGH3); triphenylamine derivatives, such as 4,4′-bis[N-(1-naphthyl)-N-phenylamino]biphenyl (α-NPD), heterocyclic derivatives, such as 9-(4,6-diphenyl-1,3,5-triazin-2-yl)-9H-carbazole and 9-(2,6-diphenylpyrimidine-4-yl)-9H-carbazole, and derivatives of these compounds.

### Surfactant

A surfactant, for example, one or two or more of fluorinated surfactants, silicone surfactants, and hydrocarbon surfactants may be used alone or in combination. Among these, silicone surfactants and/or hydrocarbon surfactants are preferred because they are less likely to trap electric charges.

The silicone surfactants and hydrocarbon surfactants may be low-molecular-weight or high-molecular-weight surfactants.

Specific examples of these include BYK series manufactured by BYK-Chemie and Surfynol manufactured by Nissin Chemical Industry Co., Ltd. Among these, silicone surfactants composed of organic modified siloxanes are suitable because a smooth coating film can be formed when an ink is applied.

### Dispersion Medium

Particles containing nanocrystals on which such a dispersant is supported are dispersed in a dispersion medium.

Examples of the dispersion medium include, but are not limited to, aromatic hydrocarbon compounds, aromatic ester compounds, aromatic ether compounds, aromatic ketone compounds, aliphatic hydrocarbon compounds, aliphatic ester compounds, aliphatic ether compounds, aliphatic ketone compounds, alcohol compounds, amide compounds, and other compounds. These may be used alone or in combination.

The aromatic hydrocarbon compounds include toluene, xylene, ethylbenzene, cumene, mesitylene, tert-butylbenzene, indan, diethylbenzene, pentylbenzene, 1,2,3,4-tetrahydronaphthalene, naphthalene, hexylbenzene, heptylbenzene, cyclohexylbenzene, 1-methylnaphthalene, biphenyl, 2-ethvinaphthalene, 1-ethylnaphthalene, octylbenzene, diphenylmethane 1,4-dimethylnaphthalene, nonyibenzene, isopropylbiphenyl, 3-ethylbiphenyl, and dodecylbenzene.

The aromatic ester compounds include phenyl acetate, methyl benzoate, ethyl benzoate, phenyl propionate, isopropyl benzoate, methyl 4-methylbenzoate, propyl benzoate, butyl benzoate, isopentyl benzoate, ethyl p-anisate, and dimethyl phthalate.

The aromatic ether compounds include dimetboxybenzene, methoxytoluene, ethyl phenyl ether, dihenzyl ether, 4-methylanisole, 2,5-dimethylanisole, ethyl phenyl ether, propyl phenyl ether, 2,5-dimethylanisole, 3,5-dimethylanisole, 4-ethylanisole, 2,3-dimethylanisole, butyl phenyl ether, p-diinethoxybenzene, p-propylanisole, m-dimethoxybenzene, methyl 2-methoxybenzoate, 1,3-dipropoxybenzene, diphenyl ether, 1-methoxynaphthalene, phenoxytoluene, 2-ethoxynaphthalene, and 1-ethoxynaphthalene.

The aromatic ketone compounds include acetophenone, propiophenone, 4′-methylacetophenone, 4′-ethylacetophenone, and butyl phenyl ketone.

The aliphatic hydrocarbon compounds include pentane, hexane, octane, and cyclohexane.

The aliphatic ester compounds include ethyl acetate, butyl acetate, ethyl lactate, hexyl acetate, butyl lactate, isoamyl lactate, amyl valerate, ethyl levulinate, γ-valerolactone, ethyl octanoate, γ-hexalactone, isoamyl hexanate, amyl hexanate, nonyl acetate, methyl decanoate, diethyl glutarate γ-heptalactone, ε-caprolactone, octalactone, propylene carbonate, γ-nonalactone, hexyl hexanoate, diisopropyl adipate, δ-nonalactone, glycerol triacetate, δ-decalactone, dipropyl adipate, δ-undecalactone, propylene glycol-1-monomethyl ether acetate, propylene glycol diacetate, diethylene glycol diacetate, diethylene glycol monoethyl ether acetate, 1,3-butanediol diacetate, 1,4-butanediol diacetate, and diethylene glycol monobutyl ether acetate.

The aliphatic ether compounds include tetrahydrofuran, dioxane, diethylene glycol dimethyl ether, diethylene glycol ethyl methyl ether, diethylene glycol isopropyl methyl ether, diethylene glycol diethyl ether, diethylene glycol butyl methyl ether, dihexyl ether, diethylene glycol dibutyl ether, diheptyl ether, and dioctyl ether.

The aliphatic ketone compounds include diisobutyl ketone, cycloheptanone, isophorone, and 6-undecanone.

The alcohol compounds include methanol, ethanol, isopropyl alcohol, 1-heptanol, 2-ethyl-1-hexanol, propylene glycol, ethylene glycol, diethylene glycol monoethyl ether, diethylene glycol monobutyl ether, ethyl 3-hydroxyhexanate, triethylene glycol monomethyl ether, tripropylene glycol monomethyl ether, diethylene glycol, cyclohexanol, and 2-butoxyethanol.

The amide compounds include N,N-dimethylacetamide, 2-pyrrolidone, N-methylpyrrolidone, and N,N-dimethylacetamide.

The other compounds include water, dimethyl sulfoxide, acetone, chloroform, and methylene chloride.

Such a dispersion medium preferably has a viscosity of approximately 1 to 20 mPa·s, more preferably approximately 1.5 to 15 MPa·s, still more preferably approximately 2 to 10 mPa·s, at 25° C. When an ink is ejected by a droplet ejection method, the dispersion medium with a viscosity in this range at normal temperature can prevent or reduce a phenomenon (satellite phenomenon) in which a droplet ejected from a nozzle orifice of a droplet ejection head separates into a main droplet and a small droplet. This can improve the landing accuracy of the droplet on the adherend.

If there is a possibility that particles containing nanocrystals in an ink according to the present invention are inactivated by oxygen, water, or the like and do not function stably, dissolved gas and water in the dispersion medium are preferably minimized before the preparation of the ink, or posttreatment after the preparation of the ink is preferably perforated to minimize dissolved oxygen and water in the ink. The posttreatment , be degassing, saturation or supersaturation with an inert gas, heat treatment, or dehydration involving a passage through a drying agent.

The dissolved oxygen and water content of the ink is preferably 200 ppm or less, more preferably 100 ppm or less, still more preferably 10 ppm or less.

The amount of particles in the ink is preferably 50% or less by mass, more preferably approximately 0.01% to 30% by mass, still more preferably approximately 0.1% to 10% by mass. When the ink is ejected by the droplet ejection method, an amount of particles in the ink in this range results in further improved ejection stability. This can also reduce the agglomeration of the particles (nanocrystals) and improve the luminous efficiency of the light-emitting layer.

The mass of the particles are the total mass of the nanocrystals and the dispersant supported on the nanocrystals.

The phrase “the amount of particles in the ink”, as used herein, refers to the mass percentage of the particles based on the total mass of the particles and a dispersion medium in the ink composed of the particles and the dispersion medium, or the mass percentage of the particles based on the total mass of the particles, a nonvolatile component other than particles, and a dispersion medium in the ink composed of the particles, the nonvolatile component, and the dispersion medium.

The dispersion medium used in the present invention have a boiling point of 200° C. or more at atmospheric pressure (1 atm) (hereinafter also referred to simply as “boiling point”). Dispersion medium with a boiling point in such a temperature range evaporate (vaporize) slowly. Thus, an ink containing such a dispersion medium ejected by the droplet ejection method is appropriately prevented from drying near a nozzle orifice of a droplet ejection head and from clogging the nozzle orifice. Consequently, the ink can have high ejection stability for extended periods and improve the efficiency of forming a light-emitting layer.

The dispersion medium has a boiling point of 200° C. or more, preferably approximately 200° C. to 340° C., more preferably approximately 210° C. to 320° C. The use of a dispersion medium with a boiling point in such a temperature range can further improve the advantages described above.

In particular, a dispersion medium containing a polar compound with a polar group is preferably used. The polar group of the polar compound has high adsorbability on nanocrystals. Thus, the polar compound has the function of adsorbing (solvating) on the surface of nanocrystals and increasing the dispersibility of the nanocrystals in the ink, that is, functions as a dispersant. Thus, the use of the polar compound can improve the storage stability of the ink.

The amount of the polar compound in the dispersion medium preferably ranges from approximately 20% to 80% by mass, more preferably approximately 30% to 70% by mass. This can appropriately control the amount of polar compound in the ink. Thus, when a coating film is dried to form a light-emitting layer, the polar compound is sufficiently removed from the light-emitting layer. This can improve the emission lifetime of the light-emitting layer (light-emitting device). In particular, the relationship to the amount of particles in the ink can be adjusted to further enhance the effects.

Examples of the polar group of the polar compound include a hydroxy group, a carbonyl group, a thiol group, an amino group, a nitro group, and a cyano group. Among these, the polar group is preferably at least one selected from the group consisting of a hydroxy group and a carbonyl group. These polar groups are preferred due to their particularly high affinity for nanocrystals.

Thus, the polar compound is preferably at least one compound selected from the group consisting of aromatic ester compounds, such as methyl benzoate, ethyl benzoate, phenyl propionate, isopropyl benzoate, methyl 4-methylhenzoate, propyl benzoate, butyl benzoate, isopentyl benzoate, ethyl p-anisate, and dimethyl phthalate; aromatic ketone compounds, such as acetophenone, propiophenone. 4′-methylacetophenone, 4° -ethylacetophenone, and butyl phenyl ketone; aliphatic ester compounds, such as hexyl acetate, isoamyl lactate, amyl valerate, ethyl levulinate, γ-valerolactone, ethyl octanoate, γ-hexalactone, isoamyl hexanate, amyl hexanate, nonyl acetate, methyl decanoate, diethyl glutarate, γ-heptalactone, ε-caprolactone, octalactone, propylene carbonate, γ-nonalactone, hexyl hexanoate, diisopropyl adipate, δ-nonalactone, glycerol triacetate, δ-decalactone, δ-undecalactone, diethylene glycol monoethyl ether acetate, 1,3-butanediol diacetate, 1,4-butanediol diacetate, and diethylene glycol monobutyl ether acetate; aliphatic ketone compounds, such as isophorone and δ-undecanone; and alcohol compounds, such as diethylene glycol monoethyl ether, triethylene glycol monomethyl ether, diethylene glycol monobutyl ether, ethyl 3-hydroxyhexanate, tripropylene glycol monomethyl ether, and diethylene glycol. These polar compounds can be used to further improve the emission lifetime of the light-emitting layer (light-emitting device).

The dispersant to be supported on the nanocrystals preferably has a weight-average molecular weight in the range of approximately 100 to 10,000 or approximately 250 to 5,000. Dispersants with such a weight-average molecular weight are easily detached from the nanocrystals, and therefore limited types of compounds can typically be used as dispersants. When a dispersion medium containing a polar compound is used, even if the dispersant is detached from the nanocrystals in the ink, the polar compound complementarily adsorbs on the nanocrystals and behaves like a dispersant. This can ensure the storage stability of the ink. In the formation of the light-emitting layer, the dispersant is reliably removed from the coating film, and the light-emitting layer (light-emitting device) can have an extended emission lifetime.

### Light-Emitting Device

A light-emitting device according to the present invention includes an anode and a cathode (a pair of electrodes), a light-emitting layer containing a dried product of an ink according to the present invention located between the electrodes, and a charge-transport layer located between the light-emitting layer and at least one electrode of the anode and the cathode.

The charge-transport layer preferably includes at least one layer selected from the group consisting of a hole-injection laver, a hole-transport layer, an electron-transport laver, and an electron-injection layer. A light-emitting device according to the present invention may further contain a sealing material.

FIG. 1 is a cross-sectional view of a light-emitting device according to an embodiment of the present invention.

In FIG. 1, for convenience, each part may have exaggerated dimensions and proportions and may be different from its actual dimensions and proportions The following materials and dimensions are only examples, and the present invention is not limited to these materials and dimensions. The materials and dimensions may be appropriately changed without departing from the gist of the present invention.

For convenience of explanation, the upper side in FIG. 1 is referred to as “the upper side” or “upper”, and the lower side in FIG. 1 is referred to as ‘the lower side’ or “lower”. In FIG. 1, to avoid complicated drawings, hatching for cross sections is omitted.

A light-emitting device 1 in FIG. 1 includes an anode 2 and a cathode 3 and includes, between the anode 2 and the cathode 3, a hole-injection layer 4, a hole-transport layer 5, a light-emitting layer 6, an electron-transport layer 7, and an electron-injection layer 8 sequentially stacked on the anode 2.

Each layer is described below.

### Anode 2

The anode 2 has the function of supplying positive holes from an external power supply to the light-emitting layer 6.

The anode 2 may be composed of any material (anode material), for example, a metal, such as gold (Au), a halogenated metal, such as copper iodide (CuI), or a metal oxide, such as indium tin oxide (ITO), tin oxide (SnO₂), or zinc oxide (ZnO). These may be used alone or in combination.

The anode 2 may have any thickness, preferably in the range of approximately 10 to 1,000 nm, more preferably approximately 10 to 200 nm.

The anode 2 can be formed by a dry film formation method, such as a vacuum evaporation method or a sputtering method, for example. The anode 2 in a predetermined pattern may also be formed by a photolithography method or a method using a mask.

### Cathode 3

The cathode 3 has the function of supplying electrons from an external power supply to the light-cutting layer 6.

The cathode 3 may be composed of any material (cathode material), for example, lithium, sodium, magnesium, aluminum, silver, a sodium-potassium alloy, a magnesium/aluminum mixture, a magnesium/silver mixture, a magnesium/indium mixture, an aluminum/aluminum oxide (Al₂O₃) mixture, or a rare-earth metal. These may be used alone or in combination.

The cathode 3 may have any thickness, preferably in the range of approximately 0.1 to 1,000 nm, more preferably approximately 1 to 200 nm.

The cathode 3 can be formed by a dry film formation method, such as an evaporation method or a sputtering method, for example.

### Hole-Injection Layer 4

The hole-injection layer 4 has the function of receiving positive holes from the anode 2 and injecting the positive holes into the hole-transport layer 5. The hole-injection layer 4 may be formed as required or may be omitted.

The hole-injection layer 4 may be composed of any material (hole-injection material), for example, a phthalocyanine compound, such as copper phthalocyanine; a triphenylamine derivative, such as 4,4′,4″-tris[phenyl(m-toly)amino]triphenylamine; a cyano compound, such as 1,4,5,8,9,12-hexaazatriphenylenehexacarbonitrile or 2, 3, 5, 6-tetrafluoro-7, 7, 8, 8-tetracyano-quinodimethane; a metal oxide, such as vanadium oxide or molybdenum oxide; amorphous carbon; or a polymer, such as polyaniline emeraldine), poly(3,4-ethylenedioxythiophene)-poly(styrenesulfonic acid) (PEDOT-PSS), or polypyrrole.

Among these, the hole-injection material is preferably a polymer, more preferably PEDOT-PSS.

The hole-injection materials may be used alone or in combination.

The hole-injection layer 4 may have any thickness, preferably in the range of approximately 0.1 to 500 nm, more preferably approximately 1 to 300 nm, still more preferably approximately 2 to 200 nm.

The hole-injection layer 4 may have a monolayer structure or a multilayer structure of two or more layers.

The hole-injection layer 4 may be formed by a wet film formation method or a dry film formation method.

In the formation of the hole-injection layer 4 by the wet film formation method, in general, an ink containing the hole-injection material is applied by an application method, and the coating film is dried. The application method may be any method, for example, an ink jet method (a droplet ejection method), a spin coating method, a casting method, a LB method, a letterpress printing method, a gravure printing method, a screen printing method, or a nozzle printing method.

The dry film formation method for the hole-injection layer 4 is preferably a vacuum evaporation method or a sputtering method.

### Hole-Transport Layer 51

The hole-transport layer 5 has the function of receiving positive holes from the hole-injection layer 4 and efficiently transporting the positive holes to the light-emitting layer 6. The hole-transport layer 5 may have the function of preventing electron transport. The hole-transport layer 5 may be formed as required or may be omitted.

The hole-transport layer 5 may be composed of away material (hole-transport material), for example, a low-molecular-weight triphenylamine derivative, such as N,N′-diphenyl-N,N′-di(3-methylphenyl)-1,1′-biphenyl-4,4′diamine (TPD), 4,4′-bis[N-(1-naphthyl)-N-phenyiamino]biphenyl (α-NPD), or 4,4′,4′-tris(3-methylphenylphenylamino)triphenylamine (m-MTDATA); polyvinylcarbazole; a conjugated compound., polymer, such as poly[N,N′-bis(4-butylphenyl)-N,N′-bis(phenyl)-benzidine](poly-TPA), polyfluorene (PF), poly[N,N′-bis(4-butylphenyl)-N,N′-bis(phenyl)-benzidine (Poly-TPD), poly[(9,9-dioctylfluorenyl-2,7-diyl)-co-(4,4′-(N-(sec-butylphenyl)diphenylamine)) (TFB), or poly(phenylene vinylene) (PPV); or a copolymer containing these monomer units.

Among these, the hole-transport material is preferably a triphenylamine derivative or a high-molecular-weight compound produced by polymerization of a triphenylamine derivative with a substituent, more preferably a high-molecular-weight compound produced by polymerization of a triphenylamine derivative with a substituent.

The hole-transport materials may be used alone or in combination.

The hole-transport layer 5 may have any thickness, preferably in the range of approximately 1 to 500 mm, more preferably approximately 5 to 300 nm, still more preferably approximately 10 to 200 nm.

The hole-transport layer 5 may have a monolayer structure or a multilayer structure of two or more layers.

The hole-transport layer 5 may be formed by a wet film formation method or a dry film formation method.

In the formation of the hole-transport layer 5 by the wet film formation method, in general, an ink containing the hole-transport material is applied by an application method, and the coating film is dried. The application method may be any method, for example, an ink jet method (a droplet ejection method), a spin coating method, a casting method, a LB method, a letterpress printing method, a gravure printing method, a screen printing method, or a nozzle printing method.

The dry film formation method for the hole-transport layer 5 is preferably a vacuum evaporation method or a sputtering method.

### Electron-Injection Layer 8

The electron-injection layer 8 has the function of receiving electrons from the cathode 3 and injecting the electrons into the electron-transport layer 7. The electron-injection layer 8 may be formed as required or may be omitted.

The electron-injection layer 8 may be composed of any material (electron-injection material), for example, an alkali metal chalcogenide, such as Li₂O, LiO, Na₂S, Na₂Se, or NaO; an alkaline-earth metal chalcogenide, such as CaO, BaO, SrO, BeO, BaS, MgO, or CaSe; an alkali metal halide, such as CsF, LiF, NaF, KF, LiC, KCl, or NaCl; an alkali metal salt, such as 8-hvdroxyquinolinolato lithium (Liq); or an alkaline-earth metal halide, such as CaF₂, BaF₂, SrF₂, MgF₂, or BeF₂.

Among these, preferred is an alkali metal chalcogenide, an alkaline-earth metal halide, or an alkali metal salt.

The electron-injection materials may be used alone or in combination.

The electron-injection layer 8 may have any thickness, preferably in the range of approximately 0.1 to 100 nm, more preferably approximately 0.2 to 50 nm, still more preferably approximately 0.5 to 10 nm.

The electron-injection layer 8 may have a monolayer structure or a multilayer structure of two or more layers.

The electron-injection layer 8 may be formed by a wet film formation method or a dry film formation method.

In the formation of the electron-injection layer 8 by the wet film formation method, in general, an ink containing the electron-injection material is applied by an application method, and the coating film is dried. The application method may be any method, for example, an ink jet method droplet ejection method), a spin coating method, a casting method, a LB method, a letterpress printing method, a gravure printing method, a screen printing method, or a nozzle printing method.

The dry film formation method for the electron-injection layer 8 may be a vacuum evaporation method or a sputtering method.

### Electron-Transport Layer 7

The electron-transport layer 7 has the function of receiving electrons from the electron-injection layer 8 and efficiently transporting the electrons to the light-emitting layer 6. The electron-transport layer 7 may have the function of preventing hole transport. The electron-transport layer 7 may be formed as required or may be omitted.

The electron-transport layer 7 may be composed of any material (electron-transport material), for example, a metal complex with a quinoline or benzoquinoline skeleton, such as tris(8-quinolinolato) aluminum (Alq3), tris(4-methyl-8-quinolinolato) aluminum (Almq3), bis(10-hydroxybenzo[h]-quinolinato) beryllium (BeBq2), bis (2-methyl-8-quinolinolato) (p-phenylphenolate) aluminum (BAlq), or bis(8-quinolinolato) zinc (Zng); a metal complex with a benzoxazoline skeleton, such as bis[2-(2′-hydroxyphenyl)henzoxazolate] zinc (Zn(BOX)2); a metal complex with a benzothiazoline skeleton, such as bis[2-(2′-hydroxyphenyl)benzothiazolate] zinc (Zn(BTZ)2); a triazole or diazole derivative, such as 2-(4-biphenylyl)-5-(4-tert-butylphenyl)-1,3,4-oxadiazole (PBD), 3-(4-biphenylyl)-4-phenyl-5-(4-tert-butylphenyl)-1,2,4-triazole (TAZ), 1,3-bis[5-(p-tert-butylphenyl)-1,3,4-oxadiazol-2-yl] benzene (OXD-7), or 9-[4-(5-phenyl-1,3,4-oxadiazol-2-yl)phenyl]carbazole (CO11); an imidazole derivative, such as 2,2′,2″-(1,3,5-henzenetriyl)tris(1-phenyl-1H-benzimidazole) (TPBI) or 2-[3-(dibenzothiophen-4-yl)phenyl]-1-1-phenyl-1H-benzimidazole (mDBTBIm-II); a quinoline derivative; a perylene derivative; a pyridine derivative, such as 4,7-diphenyl-1,10-phenanthroline (BPhe ; a pyrimidine derivative; a triazine derivative; a quinoxaline derivative; a diphenylquinone derivative; a nitro-substituted fluorene derivative; or a metal oxide, such as zinc oxide (ZnO) or titanium oxide (TiO₂).

Among these, the electron-transport material is preferably an imidazole derivative, a pyridine derivative, a pyrimidine derivative, a triazine derivative, or a metal oxide (inorganic oxide).

The electron-transport materials may be used alone or in combination.

The electron-transport layer 7 may have any thickness, preferably in the range of approximately 5 to 500 nm, more preferably approximately 5 to 200 nm.

The electron-transport layer 7 may be a monolayer or a multilayer of two or more layers.

The electron-transport layer 7 may be formed by a wet film formation method or a dry film formation method.

In the formation of the electron-transport layer 7 by the wet film formation method, in general, an ink containing the electron-transport material is applied by an application method, and the coating film is dried. The application method may be any method, for example, an ink jet method droplet ejection method), a spin coating method, a casting method, a LB method, a letterpress printing method, a gravure printing method, a screen printing method, or a nozzle printing method.

The dry film formation method for the electron-transport layer 7 may be a vacuum evaporation method or a sputtering method.

### Light-Emitting Layer 6

The light-emitting layer 6 has, the function of utilizing energy generated by recombination of positive holes and electrons injected into the light-emitting layer 6 to emit light.

The light-emitting layer 6 is formed of a dried product of an ink according to the present invention. Thus, the light-emitting layer 6 contains uniformly dispersed nanocrystals and has good luminous efficiency.

The light-emitting layer 6 may have any thickness, preferably in the range of approximately 1 to 100 nm, more preferably approximately 1 to 50 nm.

For the light-emitting layer 6, an ink according to the present invention is applied by an application method, and the coating film is dried. The application method may be any method, for example, an ink jet printing method (a piezoelectric or thermal droplet ejection method), a spin coating method, a casting method, a LB method, a letterpress printing method, a gravure printing method, a screen printing method, or a nozzle printing method.

In the nozzle printing method, an ink is applied in a striped pattern as a liquid column through a nozzle orifice.

An ink according to the present invention can be suitably applied by an ink jet printing method. In particular, ink according to the present invention is preferably applied by a piezoelectric ink jet printing method. This can decrease the heat load in ink ejection and reduce defects in particles (nanocrystals). Thus, an apparatus suitable for the application of an ink according to the present invention is an ink jet printer with a piezoelectric ink jet head.

The light-emitting device 1 may further include a bank (partition) for partitioning the hole-injection layer 4, the hole-transport layer 5, and the light-emitting layer 6, for example.

The bank may have any height, preferably in the range of approximately 0.1 to 5 μm, more preferably approximately 0.2 to 4 μm, still more preferably approximately 0.2 to 3 μm.

The bank preferably has an opening width in the range of approximately 10 to 200 μm, more preferably approximately 30 to 200 μm, still more preferably approximately 50 to 100 μm.

The bank preferably has an opening length in the range of approximately 10 to 400 μm, more preferably approximately 20 to 200 μm, still more preferably approximately 50 to 200 μm.

The bank preferably has a tilt angle in the range of approximately 10 to 100 degrees, more preferably approximately 10 to 90 degrees, still more preferably approximately 10 to 80 degrees.

### Method for Producing Light-Emitting Device

A method for producing a light-emitting device includes the step of supplying the ink described above to a substrate to form a coating film and drying the coating film to form a light-emitting layer (hereinafter also referred to as a “light-emitting layer forming step”).

Although the substrate is the hole-transport layer 5 or the electron-transport layer 7 in FIG. 1, the substrate depends on the light-emitting device to be produced.

For example, in the production of a light-emitting device composed of an anode, a hole-transport layer, a light-emitting layer, and a cathode, the substrate is the hole-transport layer or the cathode. In the production of a light-emitting device composed of an anode, a hole-injection layer, a light-emitting laver, an electron-injection layer, and a cathode, the substrate is the hole-injection layer or the electron-injection layer.

Thus, the substrate may be an anode, a hole-injection layer, a hole-transport layer, an electron-transport layer, an electron-injection layer, or a cathode. The substrate is preferably an anode, a hole-injection layer, or a hole transport layer, more preferably a hole-injection layer or a hole-transport layer, still more preferably a hole-transport layer.

In the light-emitting layer forming step, the light-emitting layer 6 is formed by a method for forming a light-emitting layer according to the present invention.

The method for forming a light-emitting layer includes [1] the first step of preparing an ink, as described above, [2] the second step of forming a coating film of the ink on a substrate, [3] the third step of removing a dispersion medium from the coating film at a first pressure, and [4] the fourth step of removing the dispersion medium from the coating film at a second pressure.
[1] First Step

First, particles containing nanocrystals on which a dispersant is supported are dispersed in a dispersion medium to prepare an ink. Alternatively, a commercial ink with such a composition may be purchased.
[2] Second Step

Before the second step, a substrate is prepared. In the present embodiment, in the way described above, the anode 2, the hole-injection layer 4, and the hole-transport layer 5 (substrate) are sequentially stacked, or the cathode 3, the electron-injection layer 8, and the electron-transport layer 7 (substrate) are sequentially stacked.

The substrate may have a bank, as described above. The formation of the bank enables the light-emitting layer 6 to be formed only in a desired portion on the substrate.

The ink is then supplied to the substrate (the hole-transport layer 5 or the electron-transport layer 7) by the application method as described above to forint a coating film on the substrate.

For example, in the droplet ejection method, the ink is applied intermittently to the substrate in a predetermined pattern through a nozzle orifice of a droplet ejection head. The droplet ejection method enables drawing and patterning with a high degree of flexibility. In particular, the piezoelectric droplet ejection method can increase the selectivity of the dispersion medium and decrease the heat load to the ink.

The ink ejection rate is preferably, but not limited to, in the range of 1 to 50 pL, more preferably 1 to 30 pL, still more preferably 1 to 20 pL, at a time.

The opening-size of the nozzle orifice preferably ranges from approximately 5 to 50 μm, more preferably approximately 10 to 30 μm. This can prevent clogging of the nozzle orifice and increase ejection accuracy.

The coating film forming temperature is preferably, but not limited to, in the range of approximately 10° C. to 50° C., more preferably approximately 15° C. to 40° C., still more preferably approximately 15° C. to 30° C. Ejection of droplets at such a temperature can reduce the crystallization of various components ((nanocrystals, a dispersant, a charge-transport material, etc.) contained in the ink.

The relative humidity at which a coating film is formed is preferably, but not limited to, in the range of approximately 0.01 ppm to 80%, more preferably approximately 0.05 ppm to 60%, still more preferably approximately 0.1 ppm to 15%, particularly preferably approximately 1 ppm to 1%, most preferably approximately 5 to 100 ppm.

A relative humidity equal to or higher than the lower limit is preferred because the conditions for forming the coating film can be easily controlled. A relative humidity equal to or lower than the upper limit is also preferred because the amount of water that is adsorbed on the coating film and may have adverse effects on the light-emitting layer 5 can be decreased.
[3] Third Step (First Drying Step)

The substrate on which the coating film is formed is then placed in a chamber (not shown), and the internal pressure of the chamber is reduced to a first pressure in the range of 1 to 500 Pa and is held at the first pressure for 2 minutes or more to remove the dispersion medium from the coating film (dry the coating film).

Because the first pressure is a moderate pressure, the drying temperature of the coating film can be adjusted to slowly remove the dispersion medium from the coating film. Thus, the light-emitting layer 6 can maintain its smoothness. In the smooth light-emitting layer 6, particles (nanocrystals) are uniformly and densely distributed. Thus, the light-emitting layer (light-emitting device) can have improved light-emitting properties (low voltage drive, a long luminance half-life).

The first pressure ranges from approximately 1 to 500 Pa, preferably approximately 1 to 350 Pa, more preferably approximately 1 to 200 Pa.

The depressurization rate in the step [3] preferably ranges from approximately 1.7×10² to 1.7×10³ Pa, more preferably approximately 2×10² to 1.5×10³ Pa. This enables the coating film to be more slowly dried.

In particular, in the present invention, the chamber is maintained at the first pressure for 2 minutes or more, preferably approximately 3 to 30 minutes, more preferably approximately 5 to 20 minutes. Taking such a sufficient time, the coating film can be slowly and reliably dried, or the dispersion medium can be removed, even at a low drying temperature of the coating film. Slowly drying the coating film can further improve the smoothness of the light-emitting layer 6.

The temperature (drying temperature) at the first pressure is preferably, hut not limited to, in the range of room temperature (25° C.) to approximately 60° C., more preferably approximately 30° C. to 50° C. Setting such a drying temperature, together with the moderate first pressure, enables the coating film to he more slowly dried.

In the step [3], after the pressure is reduced to the predetermined first pressure in the range of 1 to 500 Pa, the constant first pressure may be held for 2 minutes or more, or the first pressure may be decreased in the range of 1 to 500 Pa for 2 minutes or more.
[4] Fourth Step (Second Drying Step)

Subsequently, the internal pressure of the chamber is reduced to a second pressure that is lower than the first pressure and is held at the second pressure for a predetermined time to further remove the dispersion medium from the coating film. Thus, the dispersion medium remaining in the coating film can be more reliably removed.

The second pressure is lower than the first pressure, preferably 5×10⁻² Pa or less, more preferably in the range of 1×10−3 to 8×10⁻³ Pa.

The predetermined time (drying time) is preferably, but not limited to, in the range of approximately 2 to 30 minutes, more preferably approximately 3 to 20 minutes.

The second drying step under such conditions can significantly decrease the amount of dispersion medium remaining in the light-emitting layer 6.

The temperature (drying temperature) at the second pressure is preferably, but not limited to, in the range of room temperature (25° C.) to approximately 150° C., more preferably approximately 30° C. to 100° C. Setting such a drying temperature, together with the effects of the second pressure lower than the first pressure, enables the coating film to be more reliably dried.

In the step [4], in the same manner as in the step [3], the constant second pressure may be held for a predetermined time, or the second pressure may be decreased in a specific temperature range tor a predetermined time.

Performing the first and second drying steps under such drying conditions can uniformly and densely distribute particles (nanocrystals) in the light-emitting layer 6. Consequently, the light-emitting device can be driven at low voltage. Furthermore, not only the dispersion medium but also the dispersant can be reliably removed from the coating film, and the light-emitting layer 6 is composed substantially of nanocrystals. The light-emitting layer 6 can have an improved emission lifetime.

Although a method for forming a light-emitting layer and a method for producing a light-emitting device according to the present invention are described above, the present invention is not limited to these embodiments.

For example, a method for forming a light emitting layer and a method for producing a light-emitting device according to the present invention may further include one or more additional steps for each purpose.

### EXAMPLES

Although the present invention is more specifically described in the following examples, the present invention is not limited to these examples.
1. Removal of Particles.

Hexane was added to a toluene solution containing particles (5 mg/mL, manufactured by Aldrich; product No. 776785-5ML), which was then centrifuged. A precipitate containing the particles was collected with a filter. The particles are composed of nanocrystals with a ZnS shell and an InP core, and oleylamine supported on the nanocrystals.

Samples were taken from the precipitate and were burnt in a pyrolysis mass spectrometer to determine the weight loss. The amount of supported oleylamine was approximately 10% to 30% by mass of the nanocrystals.
2. Preparation of Ink

The particles were dispersed in δ-decalactone (boiling point: 267° C.) to prepare an ink containing 1.0% by mass particles.
3. Production of Light-Emitting Device

### Example 1

First, a positive photoresist to which a fluorinated surfactant was added was spin-coated on a glass substrate (40 mm×70 mm) on which striped ITO was patterned. The positive photoresist was then patterned by photolithography to foie a bank that partitioned a pixel 300 μm long and 100 μm wide (vertical pitch: 350 μm, traverse pitch: 150 μm). Thus, the substrate with the bank was prepared.

The thickness of the bank was measured with an optical coherence surface profiler (manufactured by Ryoka Systems Inc.). The bank had a thickness of 2.0 μm.

A 45-nm hole-injection layer, a 30-nm hole-transport layer, and a 30-nm light-emitting layer were successively formed in the pixel of the substrate with the bank using an ink jet printer (DMP2831, cartridge DNC-11610, manufactured by Fujifilm Corporation).

The hole-injection layer was formed from PEDOT/PSS (CLEVIOUS P JET), the hole-transport layer was formed from a solution of 1.0% by mass TFB in tetralin, and the light-emitting layer was formed from the ink described above.

The light-emitting layer was formed through the first and second drying steps, as described below.

First, the ink was used to form a coating film on the hole-transport layer.

The substrate with the bank on which the coating film was formed was placed in a chamber, and the internal pressure of the chamber was then reduced to 500 Pa (first pressure). The depressurization rate at which the internal pressure of the chamber was reduced was 1×10³ Pa/s.

The chamber was then held at room temperature (25° C.) and at 500 Pa for 5 minutes. Thus, the δ-decalactone was removed from the coating film.

The internal pressure of the chamber was then reduced to 8×10⁻³ Pa (second pressure). The depressurization rate at which the internal pressure of the chamber was reduced was 1×10³ Pa/s.

The chamber was then held at 40° C. and at 8×10⁻³ Pa for 10 minutes. Thus, δ-decalactone was removed from the coating film.

The substrate on which the layers up to the light-emitting layer were formed was conveyed to a vacuum evaporator, and a 40-nm electron-transport layer, a 0.5-nm electron-injection layer, and a 100-nm cathode were successively formed by evaporation.

The electron-transport layer was formed of TPBI, the electron-injection layer was formed of lithium fluoride, and the cathode was formed of aluminum.

The substrate on which the layers up to the cathode were formed was conveyed to a glove box, and a sealing glass to which an epoxy resin was applied was placed on the substrate. Thus, a light-emitting device was produced.

### Examples 2 to 20 and Comparative Examples 1 to 3

Light-emitting devices were produced in the same manner as in Example 1 except that the conditions (pressure, holding time) in the first and second drying steps were changed as shown in Tables 1 to 4.

### Comparative Example 4

A light-emitting device was produced in the same manner as in Example 1 except that the second drying step was omitted.
4. Measurement
4-1. Evaluation of Drive Voltage

An electric current was applied to the light-emitting device produced in each of the examples and comparative examples to measure the drive voltage. The drive voltage of the light-emitting device other than the light-emitting device according to the comparative example 1 was determined relative to the drive voltage of the light-emitting device according to the comparative example 1, which was taken as 100%. A lower value is indicative of better results and possible low voltage drive.
4-2. Evaluation of Emission Lifetime

An electric current was applied to the light-emitting device produced in each of the examples and comparative examples with a photodiode lifetime measuring apparatus (manufactured by System Engineers Co., Ltd.) such that the initial luminance was 100 cd/m², and the light-emitting device was continuously operated. The time that elapsed before the initial luminance decreased by half (luminance half-life) was measured. The luminance half-life of the light-emitting device other than the light-emitting device according to the comparative example 1 was determined relative to the luminance half-life of the light-emitting device according to the comparative example 1, which was taken as 100%. A higher value is indicative of better results and higher durability.

Tables 1 to 4 show these evaluation results.

TABLE 1

| | First drying step | | Second drying step | | | |
|---|---|---|---|---|---|---|
| | First | Holding | Second | Holding | Drive | Luminance |
| | pressure | time | pressure | time | voltage | half-life |
| | [Pa] | [min] | [Pa] | [min] | [%] | [%] |
| Comparative | 900 | 5 | 8 × 10⁻³ | 10 | 100 | 100 |
| example 1 | | | | | | |
| Example 1 | 500 | 5 | 8 × 10⁻³ | 10 | 93 | 280 |
| Example 2 | 190 | 5 | 8 × 10⁻³ | 10 | 88 | 347 |
| Example 3 | 11 | 5 | 7 × 10⁻³ | 10 | 85 | 420 |
| Example 4 | 1 | 5 | 7 × 10⁻³ | 10 | 86 | 480 |
| Comparative | 0.1 | 5 | 7 × 10⁻³ | 10 | 108 | 200 |
| example 2 | | | | | | |

Table 1 shows that the light-emitting devices according to the examples had a decreased drive voltage and an improved luminance half-life. This is probably because setting the first pressure in the range of 1 to 500 Pa in the first drying step enabled the dispersion medium to be slowly and sufficiently removed from the coating film. Thus, the light-emitting layer could maintain its smoothness, and consequently the particles (nanocrystals) in the light-emitting layer could be uniformly and densely distributed.

By contrast, setting the first pressure below I Pa in the first drying step as in the comparative example 2 could not decrease the drive voltage of the light-emitting device and could not improve the luminance half-life of the light-emitting device.

TABLE 2

| | First drying step | | Second drying step | | | |
|---|---|---|---|---|---|---|
| | First | Holding | Second | Holding | Drive | Luminance |
| | pressure | time | pressure | time | voltage | half-life |
| | [Pa] | [min] | [Pa] | [min] | [%] | [%] |
| Example 5 | 190 | 2 | 7 × 10⁻³ | 10 | 93 | 253 |
| Example 2 | 190 | 5 | 8 × 10⁻³ | 10 | 88 | 347 |
| Example 6 | 190 | 10 | 8 × 10⁻³ | 10 | 90 | 413 |
| Example 7 | 190 | 20 | 8 × 10⁻³ | 10 | 86 | 447 |
| Example 8 | 190 | 30 | 8 × 10⁻³ | 10 | 88 | 453 |
| Example 9 | 190 | 40 | 8 × 10⁻³ | 10 | 87 | 449 |
| Comparative | 190 | 1 | 7 × 10⁻³ | 10 | 98 | 53 |
| example 3 | | | | | | |

Table 2 shows that increasing the holding time of the first pressure in the first drying step could further decrease the drive voltage of the light-emitting device and further improve the luminance half-life of the light-emitting device.

By contrast, in the light-emitting device produced in the comparative example 3, the excessively short first drying step and the rapid drying of the coating film in the second drying step could not decrease the drive voltage and could not improve the luminance half-life.

TABLE 3

| | First drying step | | Second drying step | | | |
|---|---|---|---|---|---|---|
| | First | Holding | Second | Holding | Drive | Luminance |
| | pressure | time | pressure | time | voltage | half-life |
| | [Pa] | [min] | [Pa] | [min] | [%] | [%] |
| Example 10 | 1 | 10 | 1 × 10⁻³ | 10 | 86 | 493 |
| Example 11 | 1 | 10 | 7 × 10⁻³ | 10 | 85 | 500 |
| Example 12 | 1 | 10 | 2 × 10⁻² | 10 | 86 | 473 |
| Example 13 | 1 | 10 | 5 × 10⁻² | 10 | 93 | 307 |
| Example 14 | 1 | 10 | 8 × 10⁻² | 10 | 96 | 136 |

| | | | | | |
|---|---|---|---|---|---|
| Comparative | 1 | 10 | — | — | No luminescence |
| example 4 | | | | | |

Table 3 shows that the second drying step is essential to decrease the drive voltage of the light-emitting device and to improve the luminance half-life of the light-emitting device, and a lower second pressure could enhance the effects.

TABLE 4

| | First drying step | | Second drying step | | | |
|---|---|---|---|---|---|---|
| | First | Holding | Second | Holding | Drive | Luminance |
| | pressure | time | pressure | time | voltage | half-life |
| | [Pa] | [min] | [Pa] | [min] | [%] | [%] |
| Example 15 | 10 | 15 | 7 × 10⁻³ | 1 | 91 | 353 |
| Example 16 | 10 | 15 | 7 × 10⁻³ | 5 | 89 | 487 |
| Example 17 | 10 | 15 | 7 × 10⁻³ | 10 | 86 | 513 |
| Example 18 | 10 | 15 | 7 × 10⁻³ | 20 | 86 | 547 |
| Example 19 | 10 | 15 | 7 × 10⁻³ | 30 | 88 | 480 |
| Example 20 | 10 | 15 | 7 × 10⁻³ | 40 | 90 | 500 |

Table 4 shows that increasing the holding time of the second pressure in the second drying step could further decrease the drive voltage of the light-emitting device and further improve the luminance half-life of the light-emitting device. At a second pressure of 7×10⁻³ Pa, however, even a holding time of 30 minutes or more could not enhance the effects.
5. Effects of Different Types of Dispersion Medium

### Examples 21 to 25

Inks and light-emitting devices were produced in the same manner as in the example 15 except that the dispersion medium was changed as shown in Table 5.

The drive voltages and emission lifetimes of the light-emitting devices were evaluated as described above.

Table 5 shows these evaluation results.

TABLE 5

| | | Drive voltage | Luminance half-life |
|---|---|---|---|
| | Dispersion medium | [%] | [%] |
| Example 15 | δ-decalactone | 91 | 353 |
| Example 21 | Diphenyl ether | 98 | 210 |
| Example 22 | Dimethyl phthalate | 91 | 367 |
| Example 23 | Acetophenone | 89 | 305 |
| Example 24 | 6-undecanone | 94 | 319 |
| Example 25 | Diethylene glycol | 91 | 339 |
| | monoethyl ether | | |

Table 5 shows that the light-emitting devices produced by changing the dispersion medium had a lower drive voltage and a longer emission lifetime than the light-emitting device according to the comparative example 1. In particular, the use of a polar compound rather than a low-polarity compound, such as diphenyl ether, as a dispersion medium could reduce the agglomeration of the nanocrystals and result in better results.

### INDUSTRIAL APPLICABILITY

The present invention provides a method for forming a light-emitting layer including the steps of: preparing an ink containing particles and a dispersion medium with a boiling point of 200° C. or more at atmospheric pressure, the particles containing light-emitting semiconductor nanocrystals and a dispersant supported on the semiconductor nanocrystals; supplying the ink to a substrate to form a coating film on the substrate; placing the substrate, on which the coating film is formed, in a chamber, and reducing an internal pressure of the chamber to a first pressure in the rang: of 1 to 500 Pa and holding the first pressure for 2 minutes or more to remove the dispersion medium from the coating film; and reducing the internal pressure of the chamber to a second pressure that is lower than the first pressure and holding the second pressure for a predetermined time to further remove the dispersion medium from the coating film. Thus, the present invention can provide a method for producing a light-emitting layer with good light-emitting properties and a method for producing a light-emitting device with good light-emitting properties.

### REFERENCE SIGNS LIST

1 light-emitting device

2 anode

3 cathode

4 hole-injection layer

5 hole-transport layer

6 light-emitting layer

7 electron-transport layer

8 electron-injection layer

1. A method for forming a light-emitting layer, comprising the steps of:
preparing an ink containing particles and a dispersion medium with a boiling point of 200° C. or more at atmospheric pressure, the particles containing light-emitting semiconductor nanocrystals and a dispersant supported on the semiconductor nanocrystals;
supplying the ink to a substrate to form a coating film on the substrate;
placing the substrate, on which the coating film is formed, in a chamber, and reducing an internal pressure of the chamber to a first pressure in the range of 1 to 500 Pa and holding the first pressure for 2 minutes or more to remove the dispersion medium from the coating film; and
reducing an internal pressure of the chamber to a second pressure that is lower than the first pressure and holding the second pressure for a predetermined time to further remove the dispersion medium from the coating film.

2. The method for forming a light-emitting layer according to claim 1, wherein the temperature at which the first pressure is held ranges from room temperature to 60° C.

3. The method for forming a light-emitting layer according to claim 1, wherein the second pressure is 5×10⁻² Pa or less.

4. The method for forming a light-emitting layer according to claim 1, wherein the temperature at which the second pressure is held ranges from room temperature to 150° C.

5. The method for forming a light-emitting layer according to claim 1, wherein the predetermined time ranges from 2 to 30 minutes.

6. A method for producing a light-emitting device, comprising the steps of:
forming a light-emitting layer by the method for forming a light-emitting layer according to claim 1; and
forming an anode or cathode before or after the step of forming a light-emitting layer.
